(19) United States
(12) Patent Application Publication
(10) Pub. No.: US 2012/0126840 A1
(43) Pub. Date: May 24, 2012

(54) Semiconductor Device with Cross-shaped Bumps and Test Pads Alignment

(76) Inventors: Dong-Hyuk Lee, (US); Chi-Sung Oh, (US)

(21) Appl. No.: 13/240,738

(22) Filed: Sep. 22, 2011

(30) Foreign Application Priority Data
Nov. 24, 2010 (KR) 10-2001-0117521

(51) Int. Cl. G01R 31/3187

(52) U.S. Cl. 324/750.3

(57) ABSTRACT

A semiconductor device includes a semiconductor substrate; bumps disposed in a plurality of rows along a first axis direction of the semiconductor substrate; and test pads disposed in one or more columns along a second axis direction perpendicular to the first axis direction. The bumps and the test pads form a cross shape in the center portion of the semiconductor substrate. Disposing bumps in the central portion of the semiconductor substrate facilitates forming physical connections between stacked semiconductor devices of a semiconductor stack, regardless of the chip sizes.

### CROSS-REFERENCE TO RELATED APPLICATIONS

This application claims benefit from Korean Patent Application No. 10-2010-0117521, filed on Nov. 24, 2010, in the Korean Intellectual Property Office, the contents of which are herein incorporated by reference in their entirety.

### BACKGROUND

Embodiments of the inventive concept are directed to a semiconductor device, and more particularly, to a semiconductor device with cross-shaped bumps and test pads alignment, and an electronic system including the same.

The electronics industry has developed light-weight, small, high-speed, multi-functional, and high-performance electronic devices that are desired by users. One type of electronic product assembly technology is a chip scale package or chip size package technology. A chip scale package may reduce the thickness or size of a semiconductor package. If the semiconductor devices of a chip scale package are stacked to allow physical contact between the semiconductor devices regardless of chip sizes, bumps of the chip scale package may be disposed in a central portion of the semiconductor substrate in each of the semiconductor devices.

### SUMMARY

Embodiments of the inventive concept provide a semiconductor device with bumps and test pads disposed in a cross-shape, and an electronic system including the same.

According to an aspect of the inventive concept, there is provided a semiconductor device including a semiconductor substrate; bumps disposed in a plurality of rows along a first axis direction of the semiconductor substrate; and test pads disposed in at least one column along a second axis direction perpendicular to the first axis direction, wherein the bumps and the test pads form a cross shape in a center portion of the semiconductor substrate.

The column of test pads may be spaced apart along the second axis direction of the semiconductor substrate. Columns of test pads may be spaced apart in a first direction by a predetermined distance corresponding to a width of a connection region for connecting the bumps to the test pads.

The bumps are spaced apart between the plurality of rows by a distance corresponding to a width of a region of the two or more rows of the test pads. The bumps may be spaced apart between the plurality of rows by a distance corresponding to six rows of the bumps.

The plurality of rows of bumps may be spaced apart in the first axis direction by a width of a region of the columns of test pads. The plurality of rows of bumps may be spaced apart in the second axis direction by a distance corresponding to a height of a connection n region for connecting the bumps to the test pads.

The semiconductor device may further include a test logic circuit unit connecting a plurality of bumps and one test pad in a test.

The semiconductor substrate may be divided into quadrants by the cross shape formed by the micro bumps and the test pads, and integrated circuits may be disposed on each of quadrants of the semiconductor substrate, in such a way that each integrated circuit on each of the quadrants may operate as an independent semiconductor device.

According to another aspect of the inventive concept, there is provided an electronic system including a semiconductor device; and a processor device for controlling the semiconductor device, wherein the semiconductor device includes a semiconductor substrate; bumps disposed in a plurality of rows along a first axis direction of the semiconductor substrate; and test pads disposed in at least one column along a second axis direction perpendicular to the first axis direction, and wherein the bumps and the test pads form a cross shape in a center portion of the semiconductor substrate.

The semiconductor device and the processor may form a memory card.

The semiconductor device and the processor may form a semiconductor disk device.

According to another aspect of the inventive concept, there is provided a semiconductor device including a semiconductor substrate; bumps disposed in a plurality of rows along a first axis direction of the semiconductor substrate; and test pads disposed in at least one column along a second axis direction perpendicular to the first axis direction, wherein the column of test pads is spaced apart along the second axis direction of the semiconductor substrate by a width of the plurality of rows of bumps.

The semiconductor device may further include a connection region disposed in a central region of the semiconductor substrate where the plurality of rows of bumps would overlap the at least one column of text pads, wherein the connection region includes connections that connect a subset of bumps to a subset of test pads in one-to-one correspondence.

The bumps and the test pads may form a cross shape in a center portion of the semiconductor substrate that divides the semiconductor substrate into quadrants. Integrated circuits may be disposed on each of the quadrants of the semiconductor substrate, wherein each integrated circuit on each quadrant operates as an independent semiconductor device.

### BRIEF DESCRIPTION OF THE DRAWINGS

FIG. 1 is a cross-sectional view of a semiconductor package formed by stacking first and second semiconductor devices having chip scale packages, according to various embodiments of the inventive concept.

FIG. 2 is a plan view of a semiconductor device having a chip scale package, according to an embodiment of the inventive concept.

FIG. 3 is a block diagram of integrated circuits disposed on the semiconductor device illustrated in FIG. 2.

FIG. 4 is a plan view of a semiconductor device having a chip scale package, according to another embodiment of the inventive concept.

FIG. 5 is a plan view of a semiconductor device having a chip scale package, according to another embodiment of the inventive concept.

FIG. 6 is a plan view of a semiconductor device having a chip scale package, according to still another embodiment of the inventive concept.

FIG. 7 is a block diagram of memory circuit blocks disposed on the semiconductor device illustrated in FIG. 6.

FIG. 8 is a block diagram of an example of an electronic system including a semiconductor device according to an embodiment of the inventive concept;

FIG. 9 is a block diagram of an example of a memory system using a semiconductor device according to an embodiment of the inventive concept.

FIG. 10 is a block diagram of another example of a memory system using a semiconductor device according to an embodiment of the inventive concept.

FIG. 11 is a block diagram of a computer system including a semiconductor device according to an embodiment of the inventive concept.

### DETAILED DESCRIPTION OF EXEMPLARY EMBODIMENTS

Embodiments of the inventive concept will now be described more fully with reference to the accompanying drawings, in which exemplary embodiments of the inventive concept are shown. Embodiments of the inventive concept may, however, be embodied in many different forms and should not be construed as being limited to the exemplary embodiments set forth herein. In the drawings, like reference numerals denote like elements and the sizes or thicknesses of elements may be exaggerated for clarity of explanation.

A chip scale package is a new type of package that has many distinguishing features in comparison to a typical plastic package. One distinguishing feature of a chip scale package is its package size. According to a definition provided by an international semiconductor organization such as the Joint Electron Device Engineering Council (JEDEC) or the Electronic Industries Association of Japan (EIAJ), a chip scale package has a package size within about 1.2 times a chip size.

A chip scale package is used mostly in small, portable products such as digital camcorders, mobile phones, laptop computers, and memory cards. For example, semiconductor devices such as digital signal processors (DSPs), application specific integrated circuits (ASICs), and micro controllers would be mounted in a chip scale package. In addition, chip scale packages having mounted therein memory devices such as dynamic random access memorys (DRAMs) or flash memory are becoming more popular.

However, chip scale packages have reduced reliability, and low cost-competitiveness due to, for example, additional manufacturing equipment and larger amounts of raw and subsidiary materials that are required.

To address these issues, wafer level chip scale packages are being developed. In general, a semiconductor wafer may be manufactured by performing a general wafer manufacturing process and then separating individual chips to assemble a package. Although a package assembly process requires equipment and raw and subsidiary materials different from those required in a wafer manufacturing process, a wafer level chip scale package may be manufactured as a complete product without separating individual chips from a wafer. That is, existing manufacturing equipment or processes may also be used to manufacture a wafer level chip scale package. As such, the additional raw and subsidiary materials required to manufacture a wafer level chip scale package may be minimized.

Stacked packages in which wafer level chip scale packages are three-dimensionally stacked have also been introduced. To three-dimensionally stack wafer level chip scale packages, electrical contact is required between upper and lower chip scale packages. To form these electrical contacts, holes are formed in the semiconductor chip and through electrodes are formed in the holes.

In a method of forming through electrodes, holes are formed to a predetermined depth to penetrate a chip pad of a semiconductor chip. Then, an under bump metal (UBM) layer is formed, in which the holes are filled with metal. Lastly, a rear surface of a wafer is ground to expose end portions of the metal layer filled in the holes. The end portions of the through electrodes exposed on a ground rear surface of a wafer may be used as external contact terminals when packages are stacked.

Then, metal bumps may be formed on surfaces of the holes to allow stacked chip scale packages to electrically contact each other. The metal bumps may be formed by forming a UBM layer on a surface using a plating method and then performing a photolithography process using a photosensitive layer.

After that, to electrically connect the stacked chip scale packages to each other, solder balls may be melted on protrusions externally exposed from the metal layer formed in the holes.

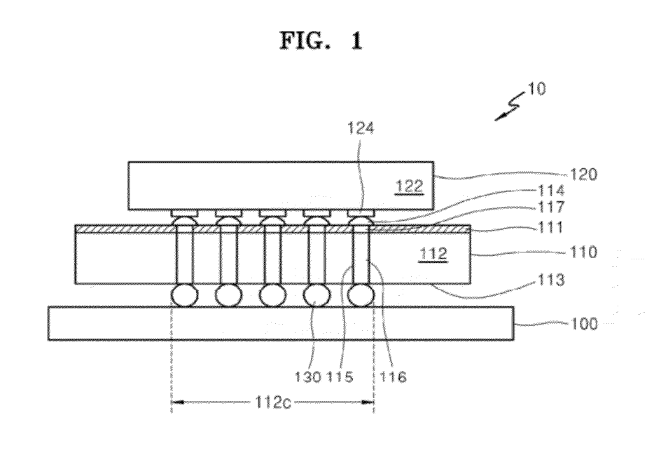

FIG. 1 is a cross-sectional view of a semiconductor package 10 formed by stacking first and second semiconductor devices 110 and 120 having chip scale packages, according to various embodiments of the inventive concept.

Referring to FIG. 1, the semiconductor package 10 may have a structure in which the first and second semiconductor devices 110 and 120 are stacked on a package substrate 100. The first and second semiconductor devices 110 and 120 may electrically contact each other via micro bumps 114 and 124.

At least one of the first and second semiconductor devices 110 and 120 may be a memory device. As will be described later, it is assumed that the first semiconductor device 110 is a memory device. However, embodiments are not limited thereto and the first semiconductor device 110 may also be a logic device.

The first semiconductor device 110 may have a semiconductor substrate 112 with an inactive surface 113 facing the package substrate 100 and an active surface 111 facing upward, and thus may be a memory device mounted on the package substrate 100 in a face-up state. Integrated circuit patterns may be formed on the active surface 111 of the first semiconductor device 110. The micro bumps 114 are formed on chip pads 117 formed in the active surface 111 of the first semiconductor device 110. The chip pads 117 are electrically connected to the integrated circuit patterns. The micro bumps 114 may be formed in a hemispherical or convex shape, and may contain nickel (Ni), gold (Au), copper (Cu), or a solder alloy. The micro bumps 114 may have a diameter of about 8 μm to about 50 μm.

The micro bumps 114 of the first semiconductor device 110 may be foil led in a central portion 112c of the semiconductor substrate 112. The micro bumps 114 are electrically connected to the second semiconductor device 120 and perform internal input/output (I/O). In an exemplary embodiment, internal I/O refers to data I/O between chips, i.e., data I/O between the first and second semiconductor devices 110 and 120.

In the first semiconductor device 110, the semiconductor substrate 112 may include one or more through electrodes 116 for performing external I/O. In an exemplary embodiment, external I/O refers to data I/O between a chip and a package substrate, i.e., data I/O between the first semiconductor device 110 and the package substrate 100.

The through electrodes 116 may be formed by forming one or more vias 115 in the central portion 112c of the semiconductor substrate 112, and then filling the vias 115 with a conductive material. The vias 115 may be formed using a laser or a dry etching method.

The through electrodes 116 electrically connect the first semiconductor device 110 to the package substrate 100, and may have a fine pitch less than or equal to, e.g., 100 um, to form a wide I/O bus. As such, the through electrodes 116 may be used in a region having a high circuit density.

Since the vias 115 have a minimal diameter for forming the through electrodes 116, the vias 115 may be formed in a front end process. The fine-pitched through electrodes 116 may increase a data transmission speed and thus may improve the electrical properties of the semiconductor package 10.

The second semiconductor device 120 may be a memory device or a logic device mounted on the active surface 111 of the first semiconductor device 110. The second semiconductor device 120 may include a semiconductor substrate 122 with the micro bumps 124 formed in a central portion thereof. The second semiconductor device 120 may be electrically connected to the first semiconductor device 110 via the micro bumps 124. The micro bumps 124 of the second semiconductor device 120 may be electrically connected to the micro bumps 114 of the first semiconductor device 110. For example, the second semiconductor device 120 may also be mounted on the first semiconductor device 110 using a flip-chip method.

In an exemplary embodiment, the micro bumps 114 and 124 of the first and second semiconductor devices 110 and 120 are formed in the central portions of the semiconductor substrates 112 and 122, to electrically connect the stacked first and second semiconductor devices 110 and 120 even when the first and second semiconductor devices 110 and 120 have different chip sizes, as illustrated in FIG. 1. That is, if stacked semiconductor devices have different chip sizes, bumps of a chip scale package may be positioned in central portions of the device substrates to facilitate physical contact between the semiconductor devices.

In other exemplary embodiments, the first and second semiconductor devices 110 and 120 may be heterogeneous chips or homogeneous chips of the same size. For example, if the first and second semiconductor devices 110 and 120 are homogeneous memory devices for forming a wide I/O bus, the micro bumps 114 and 124 and the through electrodes 116 formed in the central portions of the semiconductor substrates 112 and 122 may connect to each other the integrated circuits that are connected to the wide I/O bus. In this case, the micro bumps 114 and 124 that contact each other may be used as wide I/O balls.

The package substrate 100 may be, for example, a printed circuit board (PCB). The package substrate 100 may be electrically connected to the first semiconductor device 110 via the through electrodes 116 and one or more bulk bumps 130 contacting the through electrodes 116. The bulk bumps 130 have a greater volume and height than the micro bumps 114. Due to their larger size, the use of bulk bumps 130 disposed between the semiconductor substrate 112 and the package substrate 100 may increase stress resistance of the first semiconductor device 110 and may improve mechanical durability of the semiconductor package 10.

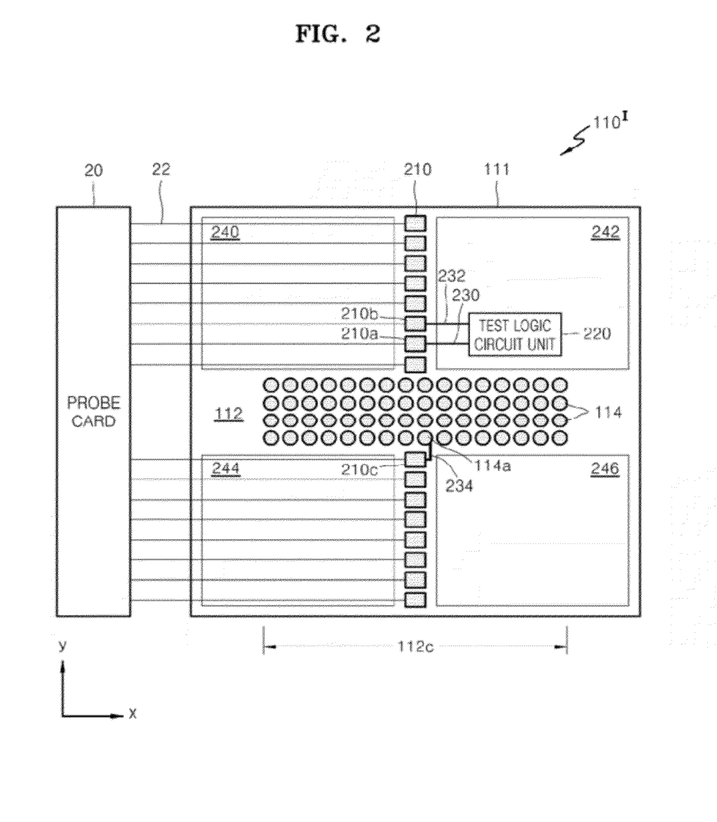

FIG. 2 is a plan view of a semiconductor device 110^{I} having a chip scale package, according to an embodiment of the inventive concept.

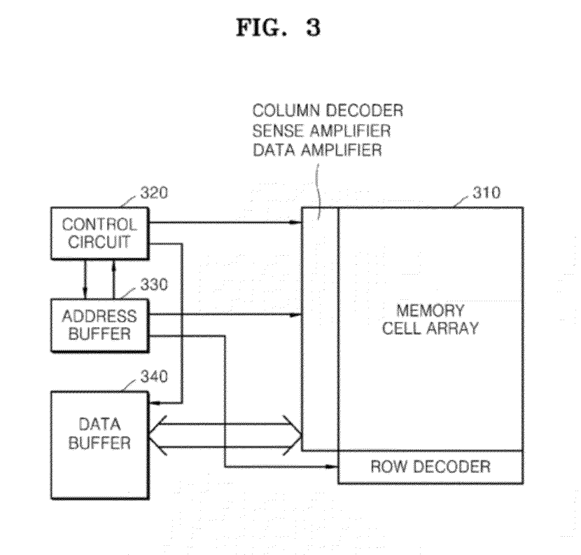

Referring to FIG. 2, the semiconductor device 110^{I} may be used as the first semiconductor device 110 illustrated in FIG. 1. FIG. 2 shows an active surface 111 of a semiconductor substrate 112 of the semiconductor device 110^{I}. Integrated circuits to be described below with reference to FIG. 3 may be formed on the active surface 111 of the semiconductor substrate 112. The semiconductor device 110^{I} includes a plurality of micro bumps 114 disposed in parallel along a first axis direction, for example, an x-axis direction, in a central portion 112c of the semiconductor substrate 112, and a plurality of test pads 210 disposed in a column extending in a second axis direction perpendicular to the first axis direction of the semiconductor substrate 112, e.g., a y-axis direction. As such, the micro bumps 114 and the test pads 210 are disposed in a cross shape in a center portion of the semiconductor substrate 112.

The micro bumps 114 are disposed in a plurality of rows in the first direction and columns in the second direction in the central portion 112c of the semiconductor substrate 112. The micro bumps 114 may be disposed in, for example, 6 rows and 50 columns. The micro bumps 114 may electrically connect to the integrated circuits. A micro bump 114 may be a control signal input terminal for receiving command control signals, such as a row address strobe signal RAS, a column address strobe signal CAS, a write enable signal WE, a reset signal RESET, and a chip selection signal CS, a clock signal terminal for receiving a clock signal CLK, an address signal terminal for receiving an address signal ADDR, a data I/O-related terminal for receiving data I/O signals such as a data strobe signal DQS, a data mask signal DM, and a data input/output signal DQ, a test-related terminal for receiving test related signals such as a test signal TEST, a direct access input signal DA, and direct access output signal DA(o), or a power terminal for receiving power supply signals such as VDD1, VDD2, VDDQ, VSS, and DQ ground signal VSSQ.

If the semiconductor device 110′ is part of a wafer level chip scale package, the micro bumps 114 may be used to perform a probe test on the semiconductor device 110^{I}. Parameter values may be varied and measured to assess the performance of the integrated circuits of the semiconductor device 110^{I}. For example, input voltage, output voltage, capacitance, and current specifications may be tested. If the semiconductor device 110^{I} is a memory device, a logic test may be performed to test data storability, data restorability, and a reaction time.

A probe card 20 having a plurality of needles 22 may perform a probe test on the semiconductor device 110^{I}. As such, the probe card 20 should have the same number of needles 22 as the number of micro bumps 114. Whether the semiconductor device 110^{I} operates normally or abnormally may be determined by allowing the needles 22 of the probe card 20 to contact corresponding micro bumps 114. For example, if the number of micro bumps 114 disposed in 6 rows and 50 columns is 300, the maximum number of needles 22 may be 300.

However, since the micro bumps 114 are concentrated in the central portion 112c of the semiconductor device 110^{I}, it may be challenging for the needles 22 to contact corresponding micro bumps 114 without the needles 22 contacting each other. Also, it may be challenging to prepare the same number of needles 22 as the number of micro bumps 114.

To address the above issues, the test pads 210 of the semiconductor device 110^{I} may be disposed in a column in a direction perpendicular to the micro bumps 114. The test pads 210 may be in one-to-one correspondence with the micro bumps 114 and thus the number of test pads 210 may equal the number of micro bumps 114. In this case, due to the test pads 210 being disposed in a column, the semiconductor device 110^{I} may have a relatively large size.

To reduce the chip size of the semiconductor device 110^{I}, the number of test pads 210 may be less than the number of micro bumps 114. A test logic circuit unit 220 may be disposed between the micro bumps 114 and the test pads 210 to connect the micro bumps 114 and the test pads 210. For example, the test logic circuit unit 220 may be a multiplexing logic circuit that allows the semiconductor device 110^{I} to perform the same operation based on signals applied to the micro bumps 114 as that performed based on a signal applied to one of the test pads 210.

The test logic circuit unit 220 may have a connection 230 to, for example, a first test pad 210a. If the semiconductor device 110^{I} is a memory device, the first test pad 210a may be set to test a read operation of the semiconductor device 110^{I}. In this case, the test logic circuit unit 220 may operate as a read control circuit of the semiconductor device 110^{I}. As such, the first test pad 210a may correspond to five micro bumps 114 allocated as control signal input terminals for receiving the RAS, CAS, WE, RESET, and CS signals for controlling the read operation.

In addition, the test logic circuit unit 220 may have a connection 232 to, for example, a second test pad 210b. If the semiconductor device 110^{I} is a memory device, the second test pad 210b may be set to test a write operation of the semiconductor device 110^{I}. In this case, the test logic circuit unit 220 may operate as a write control circuit of the semiconductor device 110^{I}. As such, the second test pad 210b may also correspond to five micro bumps 114 allocated as control signal input terminals for receiving the RAS, CAS, WE, RESET, and CS signals for controlling the write operation.

As such, a total number of test pads 210 may be less than the number of micro bumps 114.

In addition, a predetermined micro bump 114a may correspond to one of the test pads 210. For example, the micro bump 114a may have a connection 234 to an adjacent test pad 210c. In this case, a parameter tested by the test pad 210c, for example, a timing parameter, may be expected to be the same as the parameter obtained by the micro bump 114a. That is, a correlation may exist between the micro bump 114a and the test pad 210c.

Because of the cross shape configuration of the micro bumps 114 and the test pads 210 in the center portion of the semiconductor substrate 112, the semiconductor substrate 112 may be divided into first through fourth quadrants 240, 242, 244, and 246. The integrated circuits of the semiconductor device 110^{I} may be disposed on the first through fourth quadrants 240, 242, 244, and 246. If the semiconductor device 110^{I} is a memory device, as illustrated in FIG. 3, individual components of a memory cell array 310 shown in FIG. 3, such as a row decoder, a column decoder, a sense amplifier, and a data amplifier, a control circuit 320, an address buffer 330, and a data buffer 340, may be separately disposed on the first through fourth quadrants 240, 242, 244, and 246. Alternatively, all of the memory cell array 310, the control circuit 320, the address buffer 330, and the data buffer 340 may be disposed on each of the first through fourth quadrants 240, 242, 244, and 246. As such, the utilization of the integrated circuits disposed on the first through fourth quadrants 240, 242, 244, and 246 may be increased.

The test pads 210 may be formed of gold (Au), aluminum (Al), chrome (Cr), nickel (Ni), tungsten (W), titanium (Ti), tantalum (Ta), titanium tungsten (TiW), nickel chrome (NiCr), aluminum nitride (AlNx), titanium nitride (TiNx), titanium aluminum nitride (TiAlxNy), tantalum nitride (TaNx), tungsten silicide (WSix), titanium silicide (TiSix), cobalt silicide (CoSix), or a combination thereof. The test pads 210 may be formed of a material that is more flexible than the silicon used to form the semiconductor substrate 112.

When a probe test is performed on the semiconductor device 110^{I}, the test pads 210 may be torn by the needles 22 that contact the test pads 210. Particles torn from the test pads 210 may remain on the semiconductor substrate 112, and may reduce the reliability of the semiconductor device 110^{I}.

However, since the test pads 210 are spaced apart from the micro bumps 114, and since the needles 22 contact the test pads 210 in a direction (for example, an x-axis direction) parallel to a direction in which the micro bumps 114 are disposed (for example, the x-axis direction), the particles of the test pads 210 may be separated from a region of the micro bumps 114. As such, the particles may not be caught between the micro bumps 114, thus preventing the reduction in reliability of the semiconductor device 110^{I}.

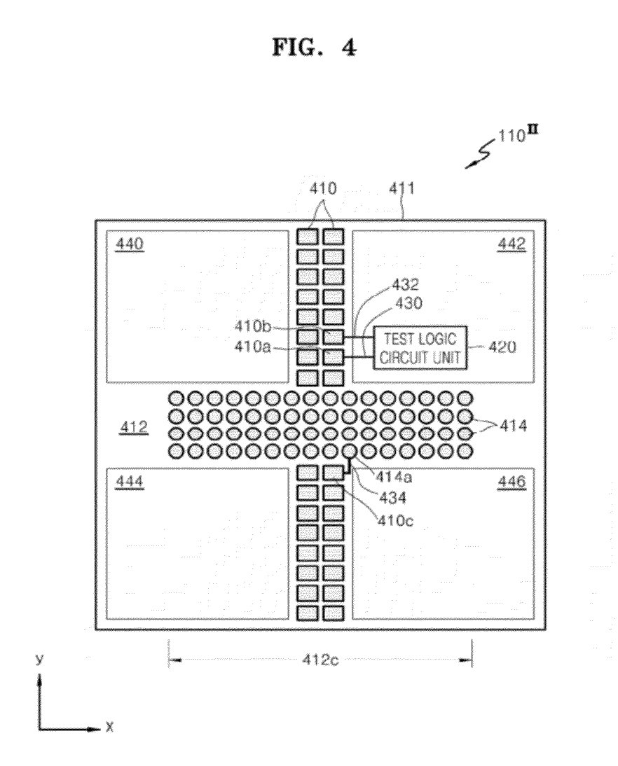

FIG. 4 is a plan view of a semiconductor device 110^{II} having a chip scale package, according to another embodiment of the inventive concept.

Referring to FIG. 4, the semiconductor device 110^{II} may be used as the first semiconductor device 110 illustrated in FIG. 1. The semiconductor device 110^{II} is similar to the semiconductor device 110^{I} illustrated in FIG. 2, except that a plurality of test pads 410 of the semiconductor device 110^{II} are disposed in two columns.

The test pads 410 are disposed in two columns extending in parallel in a y-axis direction adjacent to each other in a central portion of the semiconductor device 110^{II}.

Although the test pads 410 are disposed in two columns in FIG. 4, configurations of the test pads 410 are not limited thereto and the test pads may be disposed in a greater plurality of columns, for example, three columns or four columns. Since the test pads 410 are disposed in two adjacent columns, a chip size of the semiconductor device 110^{II} may be reduced as compared to the chip size of the semiconductor device 110^{I} in which the test pads 210 are disposed in a single column.

FIG. 4 shows an active surface 411 of a semiconductor substrate 412 in the semiconductor device 110^{II}. The integrated circuits illustrated in FIG. 3 may be formed on the active surface 411 of the semiconductor substrate 412. A plurality of micro bumps 414 is disposed in a plurality of rows and columns in a central portion 412c of the semiconductor substrate 412. The micro bumps 414 and the test pads 410 disposed in two columns are disposed in a cross shape in a center portion of the semiconductor substrate 412. Because of the cross shape configuration of the micro bumps 414 and the test pads 410 at the center portion of the semiconductor substrate 412, the semiconductor substrate 412 may be divided into first through fourth quadrants 440, 442, 444, and 446. The integrated circuits of the semiconductor device 110^{II} may be disposed on the first through fourth quadrants 440, 442, 444, and 446 of the semiconductor substrate 412.

The test pads 410 may be in one-to-one correspondence with the micro bumps 414. For example, a micro bump 414a may have an electric connection 434 to an adjacent test pad 410c. A parameter tested by the test pad 410c, for example, a timing parameter, may be expected to be the same as the parameter obtained by the micro bump 414a. That is, a correlation may exist between the micro bump 414a and the test pad 410c.

Each of the test pads 410 may correspond to a plurality of micro bumps 414 using a test logic circuit unit 420. The test logic circuit unit 420 may be a multiplexing logic circuit that allows the semiconductor device 110^{II} to perform the same operation based on signals applied to the micro bumps 414 as that performed based on a signal applied to one of the test pads 410.

The test logic circuit unit 420 may have a connection 430 to, for example, a first test pad 410a. If the semiconductor device 110^{II} is a memory device, the first test pad 410a may be set to test a read operation of the semiconductor device 110^{II}. In this case, the test logic circuit unit 420 may operate as a read control circuit of the semiconductor device 110^{II}. As such, the first test pad 410a may correspond to five micro bumps 414 allocated as control signal input terminals for receiving the RAS, CAS, WE, RESET, and CS signals for controlling the read operation.

In addition, the test logic circuit unit 420 may have a connection 432 to, for example, a second test pad 410b. If the semiconductor device 110^{II} is a memory device, the second test pad 410b may be set to test a write operation of the semiconductor device 110^{II}. In this case, the test logic circuit unit 420 may operate as a write control circuit of the semiconductor device 110^{II}. As such, the second test pad 410b may also correspond to five micro bumps 414 allocated as control signal input terminals for receiving the RAS, CAS, WE, RESET, and CS signals for controlling the write operation. Accordingly, a total number of test pads 410 may be less than the number of micro bumps 414.

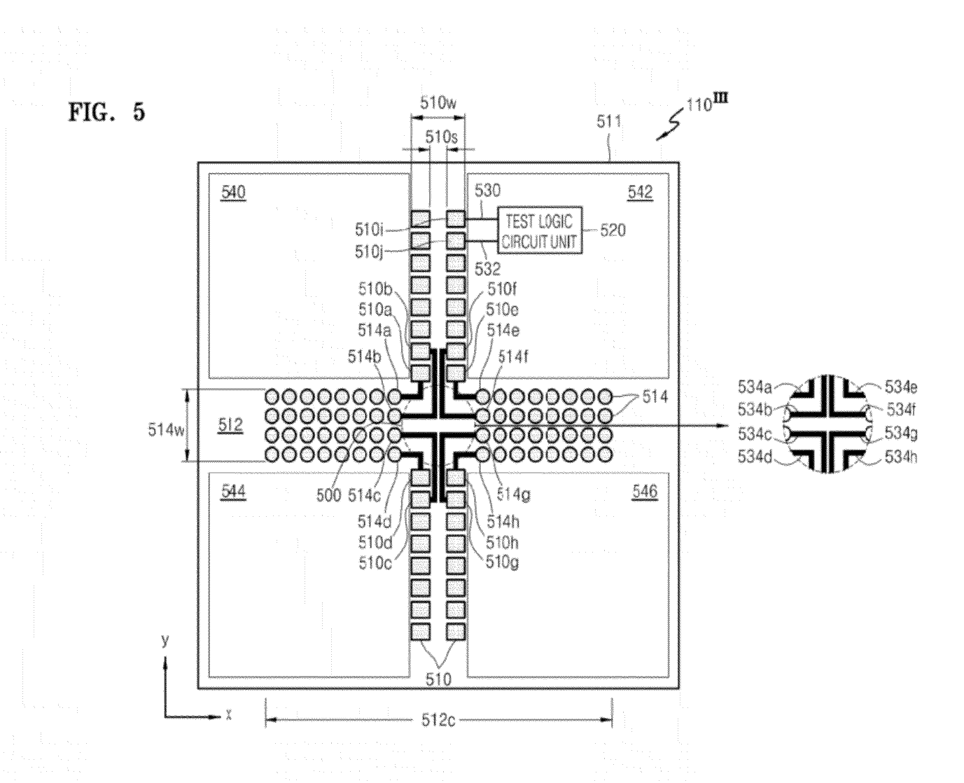

FIG. 5 is a plan view of a semiconductor device 110^{III} having a chip scale package, according to another embodiment of the inventive concept.

Referring to FIG. 5, the semiconductor device 110^{III} may be used as the first semiconductor device 110 illustrated in FIG. 1. The semiconductor device 110^{III} is similar to the semiconductor device 110^{II} illustrated in FIG. 4, except that a plurality of test pads 510 of the semiconductor device 110^{III} are disposed in two columns extending in parallel in the y-axis direction that are spaced apart by a predetermined distance 510s, and that a plurality of micro bumps 514 are spaced apart by a width 510w of the test pads 510 region.

In the semiconductor device 110^{III}, the micro bumps 514 and the test pads 510 may be disposed in a cross shape in a center portion of a semiconductor substrate 512. The micro bumps 514 are disposed in a plurality of rows and columns formed into two groups spaced apart by the width 510w along one axis direction, for example, an x-axis direction, of the test pads 510 region in a central portion 512c of the semiconductor substrate 512. The test pads 510 may be disposed in two groups of two columns that may be spaced apart by the distance 510s along the x-axis direction and by a width 514w of the micro bumps 514 region along a y-axis direction. Although the test pads 510 are disposed in two columns in FIG. 5, test pad 510 configurations are not limited thereto and may include a greater plurality of columns, for example, three columns or four columns, spaced apart by the distance 510s.

A region where the micro bumps 514 are spaced apart in the y-axis direction and where the test pads 510 are spaced apart in the x-axis direction may be located at a central region 500 of the semiconductor substrate 512. The central region 500 of the semiconductor substrate 512 may be a region where the micro bumps 514 and the test pads 510 regions overlap each other. The central region 500 of the semiconductor substrate 512 may be used as a connection region having connections that connect a subset of micro bumps 514a through 514h in one-to-one correspondence to a subset of test pads 510a through 510h.

For example, the micro bump 514a may have an electrical connection 534a to the test pad 510a. The micro bump 514b may have an electrical connection 534b to the test pad 510b. The micro bump 514c may have an electrical connection 534c to the test pad 510c. The micro bump 514d may have an electrical connection 534d to the test pad 510d. In this manner, the micro bumps 514e through 514h may have respective electrical connections 534e through 534h to the test pads 510e through 510h.

As illustrated in FIG. 5, the micro bumps 514a through 514h and the test pads 510a through 510h may be disposed adjacent to the central region 500 of the semiconductor substrate 512. A parameter tested by the test pads 510a through 510h, for example, a timing parameter, may be expected to be the same as the parameter obtained by the micro bumps 514a through 514h. As such, correlations may exist between the micro bumps 514a through 514h and the test pads 510a through 510h, respectively.

FIG. 5 shows an active surface 511 of the semiconductor substrate 512 in the semiconductor device 110^{III}. The integrated circuits illustrated in FIG. 3 may be formed on the active surface 511 of the semiconductor substrate 512. The spaced micro bumps 514 and two columns of the spaced test pads 510 may be disposed in a cross shape in the center portion of the semiconductor substrate 512 in the semiconductor device 110^{III}. Because of the cross shape configuration of the micro bumps 514 and the test pads 510 in the center portion of the semiconductor substrate 512, the semiconductor substrate 512 may be divided into first through fourth quadrants 540, 542, 544, and 546. The integrated circuits of the semiconductor device 110^{III} may be disposed on the first through fourth quadrants 540, 542, 544, and 546 of the semiconductor substrate 512.

Each of the test pads 510 may correspond to a plurality of micro bumps 514 using a test logic circuit unit 520. The test logic circuit unit 520 may be a multiplexing logic circuit that allows the semiconductor device 110^{III} to perform a same operation based on signals applied to the micro bumps 514 as that performed based on a signal applied to one of the test pads 510.

The test logic circuit unit 520 may have a connection 530 to, for example, a first test pad 510i. If the semiconductor device 110^{III} is a memory device, the first test pad 510i may be set to test a read operation of the semiconductor device 110^{III}. In this case, the test logic circuit unit 520 may operate as a read control circuit of the semiconductor device 110^{III}, and the first test pad 510i may correspond to five micro bumps 514 allocated as control signal input terminals for receiving the RAS, CAS, WE, RESET, and CS signals for controlling the read operation.

In addition, the test logic circuit unit 520 may have a connection 532 to, for example, a second test pad 510j. If the semiconductor device 110^{III} is a memory device, the second test pad 510j may be set to test a write operation of the semiconductor device 110^{III}. In this case, the test logic circuit unit 520 may operate as a write control circuit of the semiconductor device 110^{III}. As such, the second test pad 510j may also correspond to five micro bumps 514 allocated as control signal input terminals for receiving the RAS, CAS, WE, RESET, and CS signals for controlling the write operation. Accordingly, a total number of test pads 510 may be less than the number of micro bumps 514.

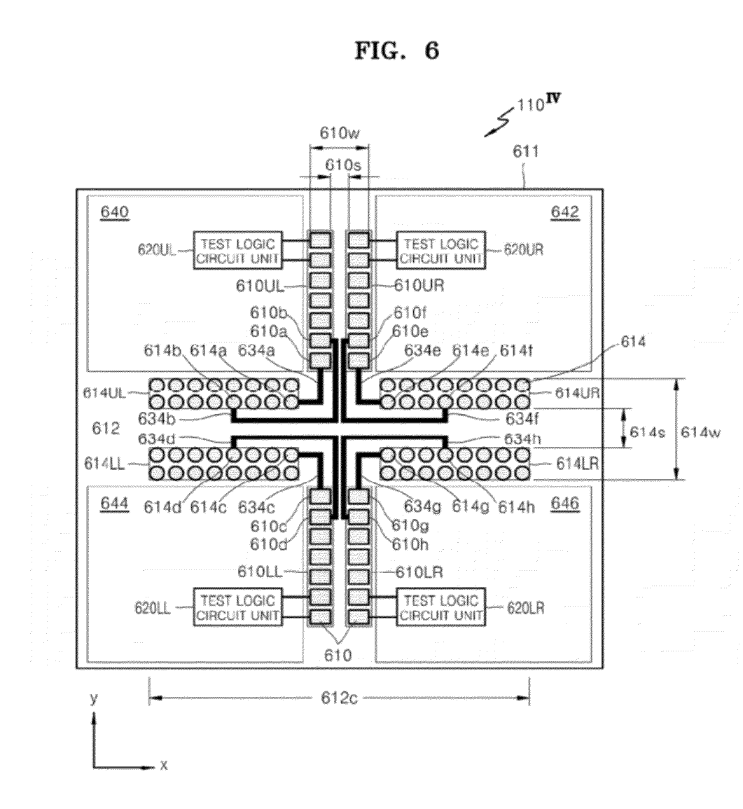

FIG. 6 is a plan view of a semiconductor device 110^{IV} having a chip scale package, according to another embodiment of the inventive concept.

Referring to FIG. 6, the semiconductor device 110^{IV} may be used as the first semiconductor device 110 illustrated in FIG. 1. The semiconductor device 110^{IV} is similar to the semiconductor device 110^{III} illustrated in FIG. 5, except that a plurality of micro bumps 614 of the semiconductor device 110^{IV} are spaced apart along one axis direction, for example, an x-axis direction, by a width 610w of a region of test pads 610 and are also spaced apart along another axis direction, for example, a y-axis direction, by a predetermined distance 614s.

In the semiconductor device 110^{IV}, the micro bumps 614 and the test pads 610 may be disposed in a cross shape in a center portion of a semiconductor substrate 612. The micro bumps 614 may be disposed in a plurality of rows and columns and are spaced apart along the x-axis direction by the width 610w of the test pads 610 region and along the y-axis direction by the distance 614s at a central portion 612c of the semiconductor substrate 612. A region where the micro bumps 614 are spaced apart and a region where the test pads 610 are spaced apart may be used as a connection region where the micro bumps 614 are connected to the test pads 610. The distance 614s may be a height of the connection region in the second axis direction.

The test pads 610 may be disposed in two columns spaced apart along the x-axis direction by a predetermined distance 610s and spaced apart along the y-axis direction by a width 614w of the micro bumps 614 region. Although the test pads 610 are disposed in two columns in FIG. 6, configurations of the test pads 610 are not limited thereto and may include a greater plurality of columns, for example, three columns or four columns, spaced apart by the distance 610s.

The regions where the micro bumps 614 and the test pads 610 are spaced apart may be used as a connection region having connections that connect a subset of micro bumps 614a through 614h to a subset of test pads 610a through 610h in one-to-one correspondence. For example, the micro bump 614a may have an electrical connection 634a to the test pad 610a. The micro bump 614b may have an electrical connection 634b to the test pad 610b. The micro bump 614c may have an electrical connection 634c to the test pad 610c. The micro bump 614d may have an electrical connection 634d to the test pad 610d. In this manner, the micro bumps 614e through 614h may have respective electrical connections 634e through 634h to the test pads 610e through 610h.

FIG. 6 shows an active surface 611 of the semiconductor substrate 612 in the semiconductor device 110^{IV}. The integrated circuits illustrated in FIG. 3 may be formed on the active surface 611 of the semiconductor substrate 612. The spaced micro bumps 614 and two columns of the spaced test pads 610 may be disposed in a cross shape in the center portion of the semiconductor substrate 612 in the semiconductor device 110^{IV}. Because of the cross shape configuration of the micro bumps 614 and the test pads 610 in the center portion of the semiconductor substrate 612, the semiconductor substrate 612 may be divided into first through fourth quadrants 640, 642, 644, and 646. The integrated circuits of the semiconductor device 110^{IV} may be disposed on the first through fourth quadrants 640, 642, 644, and 646 of the semiconductor substrate 612.

The integrated circuits may be disposed in such a way that each of the first through fourth quadrants 640, 642, 644, and 646 of the semiconductor substrate 612 may operate as an independent semiconductor device. For example, the integrated circuits disposed on the first quadrant 640, and a plurality of micro bumps 614UL and test pads 610UL connected to the first quadrant 640 may operate as one independent memory device. The integrated circuits disposed on the second quadrant 642, and a plurality of micro bumps 614UR and test pads 610UR connected to the second quadrant 642 may operate as one independent memory device. The integrated circuits disposed on the third quadrant 644, and a plurality of micro bumps 614LL and test pads 610LL connected to the third quadrant 644 may operate as one independent memory device. The integrated circuits disposed on the fourth quadrant 646, and a plurality of micro bumps 614LR and test pads 610LR connected to the fourth quadrant 646 may be designed as one independent memory device. That is, the semiconductor device 110^{IV} may be a 4-channel memory device that operates using four independent memory devices.

The micro bumps 614UL connected to the first quadrant 640 may be arranged in, for example, 6 rows and 50 columns. The micro bumps 614UR connected to the second quadrant 642 may be arranged in, for example, 6 rows and 50 columns. The micro bumps 614LL connected to the third quadrant 644 may be arranged in, for example, 6 rows and 50 columns. The micro bumps 614LR connected to the fourth quadrant 646 may be arranged in, for example, 6 rows and 50 columns.

The distance 610w between the micro bumps 614UL and the micro bumps 614UR, and between the micro bumps 614LL and the micro bumps 614LR, may be a distance corresponding to six rows of micro bumps 614. The distance 614s between the micro bumps 614UL and the micro bumps 614LL, and between the micro bumps 614UR and the micro bumps 614LR, may be a distance corresponding to two rows of micro bumps 614.

The test pads 610UL connected to the first quadrant 640 may correspond to the micro bumps 614UL using a test logic circuit unit 620UL. The test logic circuit unit 620UL may be a multiplexing logic circuit that allows the memory device of the first quadrant 640 to perform the same operation based on signals applied to the micro bumps 614UL as that performed based on a signal applied to one of the test pads 610UL.

The test pads 610UR connected to the second quadrant 642 may correspond to the micro bumps 614UR using a test logic circuit unit 620UR. The test logic circuit unit 620UR may be a multiplexing logic circuit that allows the memory device of the second quadrant 642 to perform the same operation based on signals applied to the micro bumps 614UR as that performed based on a signal applied to one of the test pads 610UR.

The test pads 610LL connected to the third quadrant 644 may correspond to the micro bumps 614LL using a test logic circuit unit 620LL. The test logic circuit unit 620LL may be a multiplexing logic circuit that allows the memory device of the third quadrant 644 to perform the same operation based on signals applied to the micro bumps 614LL as that performed based on a signal applied to one of the test pads 610LL.

The test pads 610LR connected to the fourth quadrant 646 may correspond to the micro bumps 614LR using a test logic circuit unit 620LR. The test logic circuit unit 620LR may be a multiplexing logic circuit that allows the memory device of the fourth quadrant 646 to perform the same operation based on signals applied to the micro bumps 614LR as that performed based on a signal applied to one of the test pads 610LR.

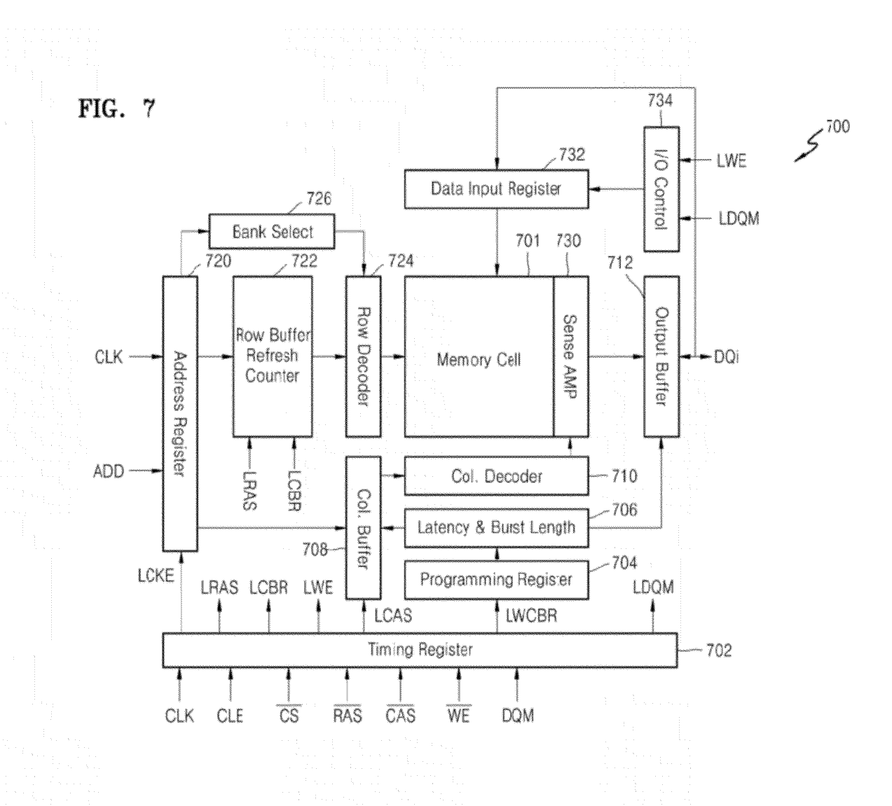

Each of the four independent channel memory devices disposed on the first through fourth quadrants 640, 642, 644, and 646 may include double data rate-synchronous dynamic random access memory (DDR-SDRAM) circuit blocks illustrated in FIG. 7. For example, a single channel memory device may be a high-bandwidth wide I/O memory device having 128-bit data I/O specifications.

Referring to FIG. 7, a single channel memory device 700 may include a memory cell array 701 having dynamic random access memory (DRAM) cells, and various circuit blocks for driving the DRAM cells. For example, a timing register 702 may be activated when a chip selection signal CS transits from an inactivation level (for example, a logic high level) to an activation level (for example, a logic low level). The timing register 702 may receive externally generated command signals, such as a clock signal CLK, a clock enable signal CLE, a chip selection signal CS, a row address strobe signal RAS, a column address strobe signal CAS, a write enable signal WE, and a data input/output mask signal DQM, and may generate various internal command signals such as an internal clock enable signal LCKE, an internal RAS command signal LRAS, an internal write enable command signal LWE, an internal CAS command signal, LCAS, internal refresh signals LCBR, LWCBR, and an internal data input/output mask signal LDQM for controlling the circuit block, by processing the received command signals.

Some internal command signals generated by the timing register 702 are stored in a programming register 704. For example, latency information or burst length information related to data output may be stored in the programming register 704. The internal command signals stored in the programming register 704 may be provided to a latency/burst length control unit 706, and the latency/burst length control unit 706 may provide a control signal for controlling a latency or a burst length of data output, to a column decoder 710 via a column buffer 708 or to a output buffer 712.

An address register 720 may receive a clock signal CLK and an address signal ADD from an external source. A row address signal may be provided to a row decoder 724 via a row buffer 722, and a column address signal may be provided to the column decoder 710 via the column buffer 708. The row buffer 722 may further receive a refresh address signal generated by a refresh counter in response to the refresh commands LRAS and LCBR, and may provide one of the row address signal and the refresh address signal to the row decoder 724. Also, the address register 720 may provide a bank signal for selecting a bank, to a bank selection unit 726.

The row decoder 724 may decode the row address signal or the refresh address signal received from the row buffer 722, and may activate a word line of the memory cell array 701. The column decoder 710 may decode the column address signal, and may select a bit line of the memory cell array 701. For example, a column selection line may be applied to the semiconductor memory device 700 and thus a selection operation may be performed by the column selection line.

A sense amplifier 730 may amplify data of a memory cell selected by the row decoder 724 and the column decoder 710, and may provide the amplified data to the output buffer 712, which may output the amplified data DQi. Data to be recorded in a data cell may be provided to the memory cell array 701 via a data input register 732, and an I/O controller 734 may control data transmission by the data input register 732, in response to internal command signals LWE and LDQM received from the timing register 702.

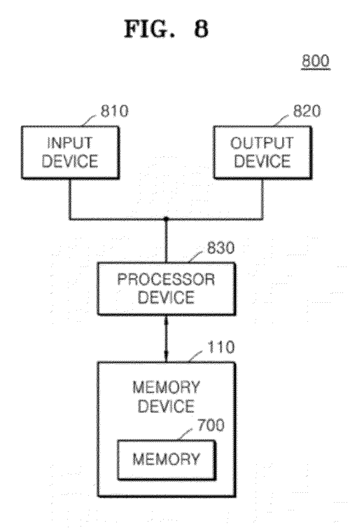

FIG. 8 is a block diagram of an electronic system 800 including a semiconductor device 110 according to an embodiment of the inventive concept.

Referring to FIG. 8, the electronic system 800 includes an input device 810, an output device 820, a processor device 830, and the semiconductor device 110. The processor device 830 may control the input device 810, the output device 820, and the semiconductor device 110 using corresponding interfaces. The processor device 830 may be one or more of a micro processor, a digital signal processor, a micro controller, or any other logic device that performs similar functions. The input device 810 and the output device 820 may include at least one of a keypad, a keyboard, a display device, etc.

The semiconductor device 110 may include a memory 700. The memory 700 may be a volatile memory device such as a DDR-SDRAM as illustrated in FIG. 7, or a non-volatile memory device such as flash memory. In the semiconductor device 110, micro bumps and test pads may be disposed in a cross shape in a center portion of a semiconductor substrate, and the test pads may be disposed in one or more columns. Also, in the semiconductor device 110, the test pads disposed in a plurality of columns may be spaced apart by a predetermined distance and may be connected to the micro bumps, and the micro bumps may be spaced apart by a distance corresponding to a width of the spaced test pads region. Furthermore, in the semiconductor device 110, the micro bumps may be spaced apart along a first axis direction of the semiconductor device 110 by a distance corresponding to a predetermined first number of rows of micro bumps, and by a distance along a second axis direction perpendicular to the first axis direction corresponding to a predetermined second number of rows of micro bumps, where the predetermined second number is less than the predetermined first number. Thus a cross-shaped region lacking micro bumps may exists within a region where the micro bumps are disposed.

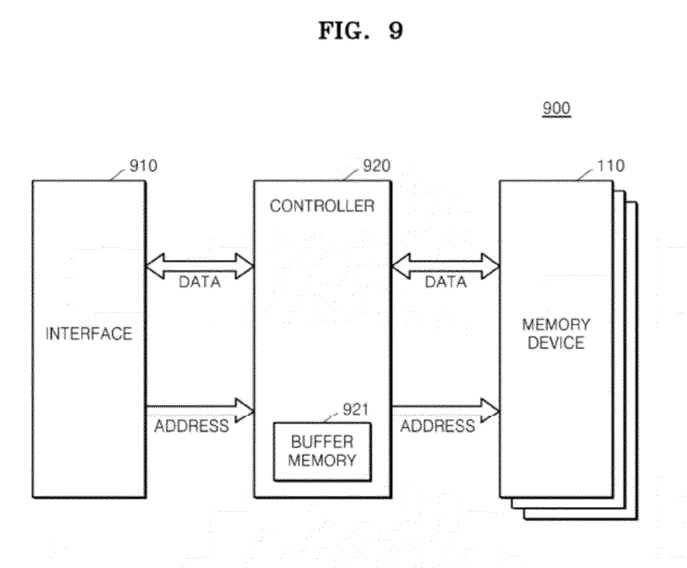

FIG. 9 is a block diagram of a first example of a memory system 900 using a semiconductor device 110 according to an embodiment of the inventive concept.

Referring to FIG. 9, the memory system 900 may include an interface unit 910, a controller 920, and the semiconductor device 110. The interface unit 910 may interface between the memory system 900 and a host. To interface with the host, the interface unit 910 may execute a data exchange protocol corresponding to the host. The interface unit 910 may communicate with the host by using one of various interface protocols, such as a universal serial bus (USB), a multi-media card (MMC), a peripheral component interconnect-express (PCI-E), a small computer system interface (SCSI), a serial-attached SCSI (SAS), a serial advanced technology attachment (SATA), a parallel advanced technology attachment (PATA), an enhanced small disk interface (ESDI), or an integrated drive electronics (IDE) protocol.

The controller 920 may receive data and addresses from the host via the interface unit 910. The controller 920 may access the semiconductor device 110 by using the data and addresses received from host. The controller 920 may transmit data read from the semiconductor memory device 110 to the host via the interface unit 910.

The controller 920 may include a buffer memory 921. The buffer memory 921 may temporarily store write data provided from the host or data read from the semiconductor device 110. Upon a read request of the host, if data stored in the semiconductor device 110 is cached, the buffer memory 921 directly provides the cached data to the host to support a cache function. In general, a data transmission speed of a bus format of the host (for example, SATA or SAS) may be greater than that of a memory channel in the memory system 900. Thus, if the host has a greater interface speed, the buffer memory 921 may minimize a performance reduction in caused by a speed difference.

In the semiconductor device 110, micro bumps and test pads may be disposed in a cross shape in a center portion of a semiconductor substrate. The semiconductor device 110 may be provided as a storing medium of the memory system 900. For example, the semiconductor device 110 may be a resistive memory device. Alternatively, the semiconductor device 110 may be a NAND-type flash memory having a large storage capacity. The semiconductor device 110 may include a plurality of memory devices. As a storing medium, the semiconductor device 110 may be a parameter random access memory (PRAM), a magneto-resistive random access memory (MRAM), a resistive random-access memory (ReRAM), a ferroelectric random access memory (FRAM), a NOR flash memory, or a memory system including heterogeneous memory devices.

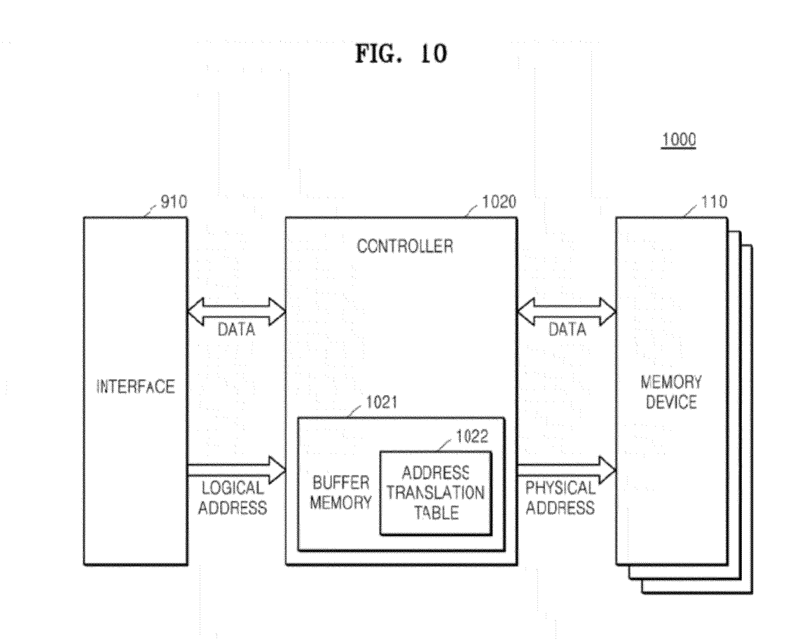

FIG. 10 is a block diagram of another example of a memory system 1000 using a semiconductor device 110 according to an embodiment of the inventive concept.

Referring to FIG. 10, the memory system 1000 includes an interface unit 910, a controller 1020, and the semiconductor device 110. As described above in relation to FIG. 9, the interface unit 910 may execute a data exchange protocol corresponding to a host to interface with the host. The semiconductor device 110 may be a semiconductor disk device (SSD) including a flash memory device in which micro bumps and test pads may be disposed in a cross shape in a center portion of a semiconductor substrate. The memory system 1000 may be a flash memory system.

The controller 1020 may include a buffer memory 1021 having an address translation table 1022. The controller 1020 may convert a logic address provided from the interface unit 910 into a physical address using the address translation table 1022. The controller 1020 may access the semiconductor device 110 using the converted physical address.

Each of the memory systems 900 and 1000 illustrated in FIGS. 9 and 10 may be mounted in a data processing device such as a personal digital assistant (PDA), a portable computer, a web tablet, a digital camera, a portable media player (PMP), a mobile phone, a wireless phone, or a laptop computer. Each of the memory systems 900 and 1000 may be a multi-media card (MMC), a secure digital (SD) card, a micro SD card, a memory stick; an identification (ID) card, a personal computer memory card international association (PCMCIA) card, a chip card, a universal serial bus (USB) card, a smart card, or a compact flash (CF) card.

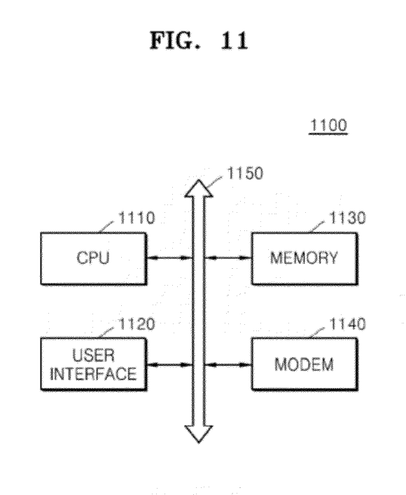

FIG. 11 is a block diagram of a computer system 1100 including a semiconductor device 110 according to an embodiment of the inventive concept.

Referring to FIG. 11, the computer system 1100 may include a central processing unit (CPU) 1110, a user interface 1120, a memory 1130, and a modem 1140 such as a baseband chipset that are electrically connected to a system bus 1150. The user interface 1120 may be an interface for transmitting or receiving data to or from a communication network. The user interface 1120 may be a wired or wireless device, and may include an antenna or a wired or wireless transceiver. Data provided by the user interface 1120 or modem 1140 or that has been processed by the CPU 1110 may be stored in the memory 1130.

The memory 1130 may include a volatile memory device such as a DRAM and/or a non-volatile memory device such as flash memory. The memory 1130 may be a DRAM, a PRAM, an MRAM, a ReRAM, a FRAM, a NOR flash memory, a NAND flash memory, or a fusion flash memory, such as a memory including an SRAM buffer, a NAND flash memory, and a NOR interface logic circuit, in which micro bumps and test pads are disposed in a cross shape in a center portion of a semiconductor substrate.

If the computer system 1100 is a mobile device, a battery (not shown) for supplying an operational voltage of the computer system 1100 may be included. Although not shown in FIG. 11, the computer system 1100 may further include, for example, an application chipset, a camera image processor (CIP), and an I/O device.

If the computer system 1100 is a wireless communication device, the computer system 1100 may be used in a communication system such as a code division multiple access (CDMA) device, a global system for mobile communication (GSM) device, a North American multiple access (NADC) device, or a CDMA2000 device.

While embodiments of the inventive concept has been particularly shown and described with reference to exemplary embodiments thereof, it will be understood that various changes in form and details may be made therein without departing from the spirit and scope of the following claims.

What is claimed is:

1. A semiconductor device comprising:
a semiconductor substrate;
bumps disposed in a plurality of rows along a first axis direction of the semiconductor substrate; and
test pads disposed in at least one column along a second axis direction perpendicular to the first axis direction,
wherein the bumps and the test pads form a cross shape in a center portion of the semiconductor substrate.

2. The semiconductor device of claim 1, wherein the column of test pads is spaced apart along the second axis direction of the semiconductor substrate by a width of the plurality of rows of bumps.

3. The semiconductor device of claim 2, wherein the test pads are disposed in two or more columns along the second axis direction of the semiconductor substrate.

4. The semiconductor device of claim 3, wherein the columns of test pads are spaced apart in the first direction by a predetermined distance corresponding to a width of a connection region for connecting the bumps to the test pads.

5. The semiconductor device of claim 4, wherein the plurality of rows of bumps are spaced apart in the first axis direction by a width of a region of the two or more columns of the test pads.

6. The semiconductor device of claim 5, wherein the plurality of rows of bumps are spaced apart in the second axis direction by a predetermined distance corresponding to a height of a connection region for connecting the bumps to the test pads.

7. The semiconductor device of claim 6, wherein the connection region includes connections that connect a subset of bumps in one-to-one correspondence to a subset of test pads.

8. The semiconductor device of claim 1, further comprising a test logic circuit unit for connecting a plurality of bumps and one test pad in a test.

9. The semiconductor device of claim 1, wherein the semiconductor substrate is divided into quadrants by the cross shape formed by the micro bumps and the test pads, and integrated circuits are disposed on each of the quadrants of the semiconductor substrate, wherein each integrated circuit on each quadrant operates as an independent semiconductor device.

10. An electronic system comprising:
a semiconductor device; and
a processor device for controlling the semiconductor device,
wherein the semiconductor device comprises:
a semiconductor substrate;
bumps disposed in a plurality of rows along a first axis direction of the semiconductor substrate; and
test pads disposed in at least one column along a second axis direction perpendicular to the first axis direction, and
wherein the bumps and the test pads form a cross shape in a center portion of the semiconductor substrate.

11. The electronic system of claim 10, wherein the rows of bumps are spaced apart in the second axis direction by a distance corresponding to a predetermined number of rows of bumps.

12. The electronic system of claim 11, wherein the bumps are spaced apart in the first axis direction by a distance corresponding to a width of the at least one column of test pads.

13. The electronic system of claim 12, wherein the column of test pads is spaced apart along the second axis direction of the semiconductor substrate by a width of the plurality of rows of bumps.

14. The electronic system of claim 13, wherein the test pads are disposed in two or more columns, and the columns of test pads are spaced apart in the first direction by a predetermined distance corresponding to a width of a connection region for connecting the bumps to the test pads.

15. A semiconductor device comprising:
a semiconductor substrate;
bumps disposed in a plurality of rows along a first axis direction of the semiconductor substrate; and
test pads disposed in at least one column along a second axis direction perpendicular to the first axis direction,
wherein the column of test pads is spaced apart along the second axis direction of the semiconductor substrate by a width of the plurality of rows of bumps.

16. The semiconductor device of claim 15, further comprising:
a connection region disposed in a central region of the semiconductor substrate where the plurality of rows of bumps overlaps the at least one column of text pads,
wherein the connection region includes connections that connect a subset of bumps to a subset of test pads in one-to-one correspondence.

17. The semiconductor device of claim 16, wherein the plurality of rows of bumps are spaced apart in the first axis direction by a width of the connection region.

18. The semiconductor device of claim 15, further comprising two or more columns of test pads, where the columns of test pads are spaced apart in the first axis direction.

19. The semiconductor device of claim 15, wherein the bumps and the test pads form a cross shape in a center portion of the semiconductor substrate that divides the semiconductor substrate into quadrants, and further comprising integrated circuits disposed on each of the quadrants of the semiconductor substrate, wherein each integrated circuit on each quadrant operates as an independent semiconductor device.
